(19) United States
(12) Patent Application Publication
(10) Pub. No.: US 2023/0335400 A1
(43) Pub. Date: Oct. 19, 2023

(54) METHOD FOR PRODUCING SEMICONDUCTOR DEVICE, SEMICONDUCTOR DEVICE, ELECTRONIC DEVICE, METHOD FOR PRODUCING SEMICONDUCTOR EPITAXIAL SUBSTRATE, AND SEMICONDUCTOR EPITAXIAL SUBSTRATE

(71) Applicant: KYOCERA Corporation, Kyoto-shi, Kyoto (JP)

(72) Inventor: Katsuaki MASAKI, Kyoto-shi, Kyoto (JP)

(73) Assignee: KYOCERA Corporation, Kyoto-shi, Kyoto (JP)

(21) Appl. No.: 18/011,658

(22) PCT Filed: Jun. 22, 2021
(86) PCT No.: PCT/JP2021/023655

§ 371 Date: Dec. 20, 2022

(30) Foreign Application Priority Data
Jun. 22, 2020 (JP) 2020-107315

(51) Int. Cl. H01L 21/02; H01L 29/20

(52) U.S. Cl. CPC H01L 21/02389; H01L 29/2003; H01L 21/02458; H01L 21/0254

(57) ABSTRACT

A method for producing a semiconductor device includes: preparing a template substrate including an underlying substrate and a mask including an opening portion and a mask portion; forming a first semiconductor portion from above the opening portion over a first region of the mask portion; and forming a second semiconductor portion located above the first semiconductor portion and containing gallium and aluminum, and a third semiconductor portion located on a second region of the mask portion where the first semiconductor portion is not formed and containing aluminum.

### TECHNICAL FIELD

The present disclosure relates to a semiconductor device.

### BACKGROUND OF INVENTION

A method of joining a semiconductor layer to a support substrate different from an underlying substrate after forming the semiconductor layer on the underlying substrate, and then separating the support substrate and the semiconductor layer from each other has been under study using various semiconductor materials (see, for example, Patent Document 1 below). Nevertheless, further improvement in the characteristics of a semiconductor device is demanded.

### CITATION LIST

### Patent Literature

Patent Document 1: WO 2005/022620

### SUMMARY

A method for producing a semiconductor device of the present disclosure includes: preparing a template substrate including an underlying substrate and a mask including an opening portion and a mask portion; forming a first semiconductor portion from above the opening portion over a first region of the mask portion; and forming a semiconductor portion located above a second region of the mask portion where the first semiconductor portion is not formed and containing a gallium congener.

### BRIEF DESCRIPTION OF THE DRAWINGS

FIG. 1 is a cross-sectional view for describing a method for producing a semiconductor epitaxial substrate of an embodiment of the present disclosure.

FIG. 2 is a diagram illustrating an electron microscope image of a deposition inhibiting mask surface on which an AlGaN debris film is formed.

FIG. 3 is a diagram illustrating an example of a design value of a composition distribution of main component elements in a thickness direction of a semiconductor element according to the present embodiment.

FIG. 4A is a diagram illustrating an electron microscope image of the deposition inhibiting mask surface on which the debris film is formed.

FIG. 4B is a diagram illustrating an electron microscope image of a deposition inhibiting mask surface without the debris film.

FIG. 5 is a diagram illustrating the edge growth height of a semiconductor layer in a case where semiconductor crystals containing aluminum are used and in a case where semiconductor crystals not containing aluminum are used for a first semiconductor layer.

FIG. 6A is a diagram illustrating an electron microscope image of a cross section of a semiconductor layer without the debris film.

FIG. 6B is a diagram illustrating an electron microscope image of a cross section of a semiconductor layer with the debris film.

FIG. 7 is a plan view illustrating a method for producing a semiconductor device according to a second embodiment.

FIG. 8 is a flowchart illustrating the method for producing the semiconductor device according to the second embodiment.

FIG. 9 is a schematic cross-sectional view illustrating the method for producing the semiconductor device in FIG. 8.

FIG. 10 is a flowchart illustrating another method for producing the semiconductor device according to the second embodiment.

FIG. 11 is a schematic cross-sectional view illustrating the method for producing the semiconductor device in FIG. 10.

FIG. 12 is a cross-sectional view illustrating a configuration of an underlying substrate according to the second embodiment.

FIG. 13 is a cross-sectional view illustrating a configuration of the semiconductor device according to the second embodiment.

FIG. 14 is a cross-sectional view illustrating another configuration of the semiconductor device according to the second embodiment.

FIG. 15 is a flowchart illustrating a method for producing the semiconductor device in FIG. 14.

FIG. 16 is a cross-sectional view illustrating another configuration of the semiconductor device according to the second embodiment.

FIG. 17 is a cross-sectional view illustrating another configuration of the semiconductor device according to the second embodiment.

FIG. 18 is a flowchart illustrating a method for producing the semiconductor device in FIG. 16 and FIG. 17.

FIG. 19 is a schematic diagram illustrating a configuration of an electronic device according to the second embodiment.

### DESCRIPTION OF EMBODIMENTS

### First Embodiment

A first embodiment of the present disclosure will be described below with reference to the drawings.

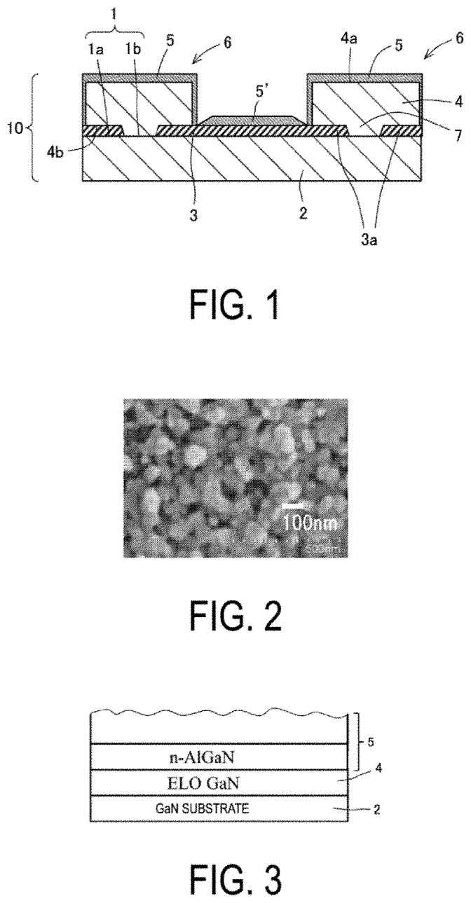

FIG. 1 is a cross-sectional view for describing a method for producing a semiconductor epitaxial substrate 10 of an embodiment of the present disclosure. The method for producing the semiconductor epitaxial substrate 10 of the present embodiment includes a mask forming step, a first semiconductor layer forming step, and a second semiconductor layer forming step. The mask forming step is a step of forming, on a partial region 1a, a deposition inhibiting mask 3 that inhibits growth of semiconductor crystals, the partial region 1a being a first partial region of a growth surface 1 of a substrate 2 including the growth surface 1 that is for example a flat first surface, including a starting point of the growth of the semiconductor crystals, to form a mask forming body in which a surface of the growth surface 1 not covered with the deposition inhibiting mask 3 is a crystal growth region 1b that is a second partial region. The first semiconductor layer forming step is a step of growing semiconductor crystals from the crystal growth region 1b over the deposition inhibiting mask 3 through vapor-phase growth to form a first semiconductor layer 4. The second semiconductor layer forming step is a step of growing semiconductor crystals on the first semiconductor layer 4 though vapor-phase growth to form a second semiconductor layer 5 at least a portion of which in contact with the first semiconductor layer 4 contains aluminum.

The deposition inhibiting mask 3 is formed to contain, for example, silicon oxide. The substrate 2 is formed to contain, for example, a gallium nitride (GaN) single crystal.

The present embodiment further includes a mask removing step of removing the deposition inhibiting mask 3 after the second semiconductor layer forming step, and a support substrate joining step of joining the second semiconductor layer 5 and a support substrate after the mask removing step.

The second semiconductor layer 5 is formed to contain a nitride semiconductor containing aluminum Al (AlGaN) at least in a portion in contact with the first semiconductor layer 4.

In the second semiconductor layer forming step, a non-single crystal film of a nitride semiconductor containing aluminum is first formed in a portion on the deposition inhibiting mask 3 where the first semiconductor layer 4 is not formed.

Mask Forming Step

In the mask forming step according to the embodiment, the substrate 2 is first prepared as an underlying substrate. The substrate 2 is an off-angle substrate. The normal line of the growth surface 1 of the substrate 2 may be inclined by 0.3° from the a-axis <11-20> direction, for example. Note that a substrate with an off angle relative to the a-axis being in a range from 0.1° to 1° can be used as the substrate 2.

As the substrate 2, for example, a GaN substrate cut out from a GaN single-crystal ingot so that the growth surface 1 of the substrate 2 is in a predetermined plane direction can be used. The substrate 2 may be a nitride semiconductor substrate. Alternatively, an n-type substrate or a p-type substrate in which the nitride semiconductor is doped with impurities may be used.

The “nitride semiconductor” used herein is, for example, formed by Al_{X}Ga_{Y}In_{Z}N (0≤X≤1; 0≤Y≤1; 0≤Z≤1; X+Y+Z=1). Specific examples of the nitride semiconductor include a GaN-based semiconductor, aluminum nitride (AlN), indium aluminum nitride (InAlN), and indium nitride (InN). The GaN-based semiconductor is a semiconductor containing gallium atoms (Ga) and nitrogen atoms (N). Typical examples of the GaN-based semiconductor include GaN, AlGaN, AlGaInN, and InGaN. For example, sapphire, Si, or SiC can be used for the substrate 2.

Next, a mask layer including the deposition inhibiting mask 3 is formed on the growth surface 1 of the substrate 2. First of all, approximately 100 nm of silicon oxide (for example, SiO₂) serving as a material of the mask layer, is deposited on the growth surface 1 of the substrate 2 by a plasma chemical vapor deposition (PCVD) method or the like. Subsequently, the SiO₂ layer is patterned by a photolithography method and wet etching with buffered hydrofluoric acid (BHF). Thus, the mask forming body including the deposition inhibiting mask 3 is formed.

The deposition inhibiting mask 3 has a stripe shape in which a plurality of strip shape portions 3a are arranged in parallel at predetermined intervals. The width of an opening portion between adjacent strip shape portions 3a is, for example, approximately 2 μm to 20 μm. The width of each of the strip shape portions 3a is, for example, approximately from 50 μm to 200 μm.

The mask material for forming the deposition inhibiting mask 3 may be any material from which a semiconductor layer does not grow from the mask material through vapor-phase growth, as an alternative to SiO₂, which is an example of silicon oxide. As the mask material, for example, a nitride such as a silicon nitride (SiN_{X}) or TiN, or an oxide such as ZrO_{X}, TiO_{X}, or AlO_{X}, all of which can be patterned, or a transition metal such as W or Cr can be used. Among these, SiO₂ can be easily removed with BHF or the like, and thus is particularly suitably used as the mask material for the sake of facilitation of a subsequent step of removing the deposition inhibiting mask 3. Note that the deposition inhibiting mask 3 is preferably formed to contain one or more types selected from silicon oxides and silicon nitrides. As the method for layering the deposition inhibiting mask 3, any method that is suitable for the mask material, such as vapor deposition, sputtering, or coating and curing, can be used as appropriate.

First Semiconductor Layer Forming Step

Subsequently, the first semiconductor layer 4, which is a crystal growth layer of semiconductor crystals, is vapor-phase grown from the crystal growth region 1b of the growth surface 1 exposed from the opening portion between the strip shape portions 3a. The first semiconductor layer 4 of the present disclosure is a nitride semiconductor layer.

As a method of crystal growth, metalorganic vapor phase epitaxy (MOVPE) using an organic metal as a group III element raw material, or hydride vapor phase epitaxy (HVPE) using a chloride may be employed.

When crystals are grown beyond the opening portion of the deposition inhibiting mask 3, crystals are grown also in the lateral direction along the upper surface of the deposition inhibiting mask 3. The crystal growth is completed before the first semiconductor layer 4 grown from the crystal growth region 1b overlaps with an adjacent first semiconductor layer 4.

In this manner, the first semiconductor layer 4 is obtained by growing the nitride semiconductor by an ELO method. The first semiconductor layer 4 includes a first surface 4a and a second surface 4b located on the opposite side to the first surface 4a. The width of the first semiconductor layer 4 is, for example, approximately from 50 μm to 200 μm, and the height thereof is approximately from 10 μm to 50 μm.

Second Semiconductor Layer Forming Step

After growing the first semiconductor layer 4, the second semiconductor layer 5 is formed on the first surface 4a of the first semiconductor layer 4, the second semiconductor layer 5 containing aluminum at least in a portion in contact with the first semiconductor layer 4. When the layer containing aluminum is formed, a non-single-crystal film 5′ containing aluminum is also formed at the same time in a portion on the deposition inhibiting mask 3 where the first semiconductor layer 4 is not formed. The layer structure of the second semiconductor layer 5 and the composition of each layer are designed as appropriate in accordance with any device structure such as a light-emitting diode (LED), a semiconductor laser (laser diode (LD)), or a photodiode (PD). The thickness of the second semiconductor layer 5 is, for example, approximately from 1 μm to 5 μm.

After the second semiconductor layer 5 is formed, the substrate 2, the deposition inhibiting mask 3, the first semiconductor layer 4, and the second semiconductor layer 5 are immersed in BHF for approximately 10 minutes to remove the deposition inhibiting mask 3. As a result, a semiconductor element portion 6 is formed on the substrate 2 in which the surface of the first semiconductor layer 4 is covered with the second semiconductor layer 5. The semiconductor element portion 6 and the substrate 2 are connected to the substrate 2 via a connecting portion 7, for example, having a columnar shape that is a part of the first semiconductor layer 4 grown in the opening portion of the deposition inhibiting mask 3.

In the second semiconductor layer forming step described above, when AlGaN is grown as a second semiconductor constituting the second semiconductor layer 5, a debris film is formed on the deposition inhibiting mask 3 composed of SiO₂. In the present embodiment, the debris film refers to a nitride semiconductor polycrystalline film that is formed on the deposition inhibiting mask 3 and has a maximum length of about several hundreds of nanometers in plan view, for example. Such a debris film is formed as follows. Specifically, Al has high reactivity and does not migrate easily, and thus adheres to the surface of the deposition inhibiting mask 3. This serves as a nucleus from which the AlGaN debris film, as can be seen in an electron microscope image in FIG. 2, is formed. Since the AlGaN debris film does not function as a deposition inhibiting mask, the layer in the subsequent second semiconductor layer forming step is also formed on the debris film.

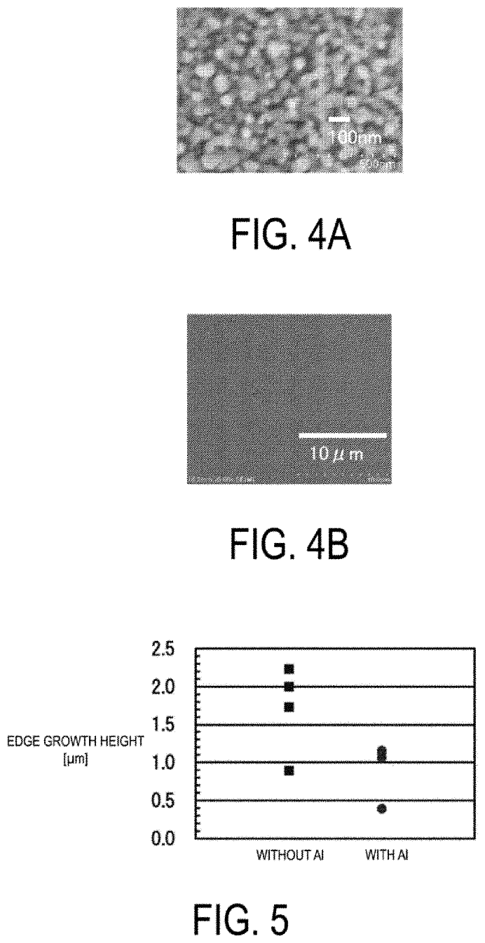

FIG. 3 is a diagram illustrating an example of a design value of a composition distribution of main component elements in a thickness direction of a semiconductor element according to the present embodiment. FIG. 4A is an electron microscope image of a semiconductor surface on which the debris film is formed, and FIG. 4B is an electron microscope image illustrating a semiconductor surface without the debris film.

When the crystals are grown only in a region not covered with the deposition inhibiting mask 3, so-called edge growth occurs. This is a phenomenon in which a growth layer thickness becomes large near the boundary between a portion covered with an insulating film and a portion not covered with the insulating film.

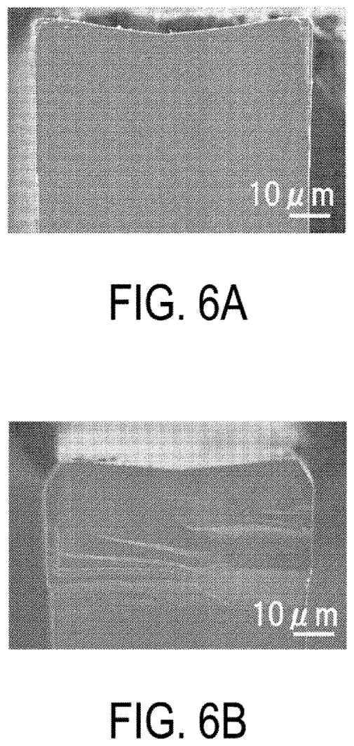

FIG. 5 is a diagram illustrating the edge growth height of the semiconductor layer in a case where semiconductor crystals containing aluminum are used and in a case where semiconductor crystals not containing aluminum are used for a portion of the second semiconductor 5 that is in contact with the first semiconductor layer 4. FIG. 6A is a diagram illustrating an electron microscope image of a cross section of a semiconductor layer without the debris film. FIG. 6B is a diagram illustrating an electron microscope image of a cross section of a semiconductor layer with the debris film.

When the semiconductor crystals containing aluminum are not used in the portion of the second semiconductor layer 5 that is not in contact with the first semiconductor layer 4, as illustrated in FIG. 6A, the crystal growth proceeds at both ends of the upper surface of the semiconductor layer compared with the center, and thus edge growth is observed. On the other hand, when semiconductor crystals containing aluminum are used in the second semiconductor layer 5, as illustrated in FIG. 6B, the upper surface of the semiconductor layer is substantially flat, and the migration effect of the type III raw material on the deposition inhibiting mask 3 is reduced by the debris film, and the edge growth is inhibited.

The following is a description of the confirmed suppression of mask impurities by the debris film. Table 1 shows the relationship between the Si concentration and the thickness of each layer constituting the semiconductor laminate, obtained by secondary ion mass spectrometry (SIMS). In Table 1, for the sake of simplicity, some of the numerical values are expressed by floating point numbers ((mantissa)×(radix) (exponent)), where the radix is 10. For example, “2E18” in Table 1 indicates “2×10¹⁸”.

TABLE 1

| | LED without | LED with | |
|---|---|---|---|
| Name | debris film | debris film | Flat LED |
| Layer structure | p-GaN | p-GaN | p-GaN |
| | p-AlGaN | p-AlGaN | p-AlGaN |
| | InGaN MQW | InGaN MQW | InGaN MQW |
| | n-GaN | n-AlGaN | n-AlGaN |
| | ELO GaN | ELO GaN | GaN template |
| | | | substrate |
| p-AlGaN layer thickness | 81 nm | 41 nm | 32 nm |
| Si concentration of | 2E18/cm³ | Less than | Less than |
| p-AlGaN layer | | 6E16/cm³ | 8E17/cm³ |

Table 1 shows the thickness of a p-AlGaN layer and the Si impurity concentration, as an example of LEDs having different layer structures. Here, the flat LED in Table 1 refers to an epitaxial substrate having an LED structure grown on the entire surface of the semiconductor substrate without using a deposition inhibiting mask. MQW is short for multi quantum well.

For example, comparing p-AlGaN layers of “LED without debris film” and “LED with debris film”, the Si concentration is lower in “LED with debris film” than in “LED without debris film”. This is expected to be due to the debris film provided inhibiting Si autodoping. The thickness of “LED with debris film” is smaller than that of “LED without debris film”, and is close to the thickness of the p-AlGaN layer of the flat LED. This is expected to be due to the debris film inhibiting supply of the raw material on the deposition inhibiting mask 3 to the second semiconductor layer 5. The above-described expectation is backed by the fact that the thickness and the Si concentration of the p-AlGaN layer in “LED with debris film” are closer to those of the p-AlGaN layer in “flat LED”, than those of the p-AlGaN layer in “LED without debris film”.

According to the present embodiment described above, after the first semiconductor layer 4 is grown on the growth surface 1 of the substrate 2 to be an underlying layer of the semiconductor device layer, the second semiconductor layer 5 is grown to cover the deposition inhibiting mask 3. As a result, the crystal growth layer to be a device layer can be uniformly formed, and mixing of decomposition products of the deposition inhibiting mask into the second semiconductor layer 5 can be reduced.

In the present embodiment, when GaN growth is implemented with epitaxial lateral overgrowth (ELO), since the SiO₂ mask is useful as a deposition inhibiting mask, the GaN growth is implemented using SiO₂ so that layers grown through ELO are not associated each other. The present embodiment is free of the problem that a p layer is difficult to grow due to GaN being doped with Si, which is an n-type dopant resulting from decomposition of SiO₂, as a result of crystal growth through ELO. The present embodiment is also free of the problem that a uniform layer is difficult to form due to edge growth, which is a phenomenon in which the growth rate is higher in corner portions than in a center portion of a layer grown through ELO when forming a device layer. The present embodiment is also free of the problem that an epitaxial lateral overgrowth condition that is the same as that on a flat GaN layer is difficult to apply to a GaN element layer that is a subsequent growth layer, due to a difference in the growth rate on the GaN layer and on the GaN element layer under the same growth conditions.

The deposition inhibiting mask may be provided using any mask material from which a semiconductor layer does not grow through vapor-phase growth, as an alternative to SiO₂, which is an example of silicon oxide. As the deposition inhibiting mask, for example, a nitride such as a silicon nitride (SiNₓ) or TiN, or an oxide such as ZrO_{X}, TiO_{X}, or AlO_{X}, all of which can be patterned, or a transition metal such as W or Cr can be used, and the same or similar effect can also be obtained with these.

The semiconductor epitaxial substrate of the present disclosure can be produced by, after the first semiconductor layer 4 is grown on the growth surface 1 of the substrate 2 to be an underlying layer of the device layer, growing the second semiconductor layer 5 to cover the deposition inhibiting mask 3. With this configuration, a semiconductor crystal layer to be the device layer can be uniformly formed, whereby the semiconductor epitaxial substrate 10 with excellent quality can be provided.

### Second Embodiment

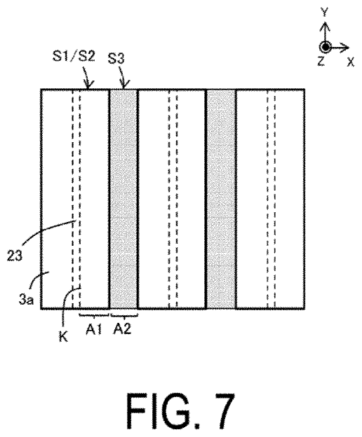

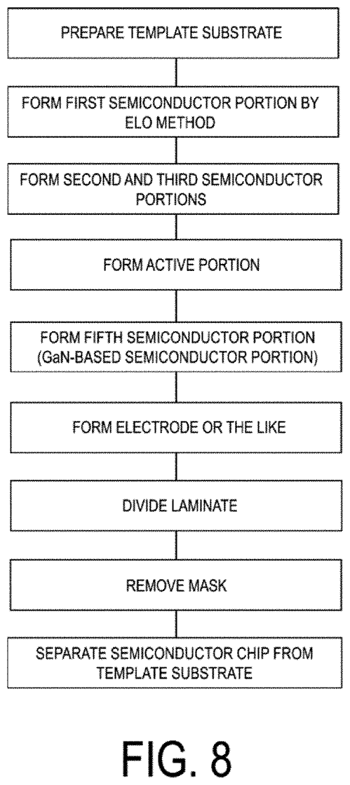

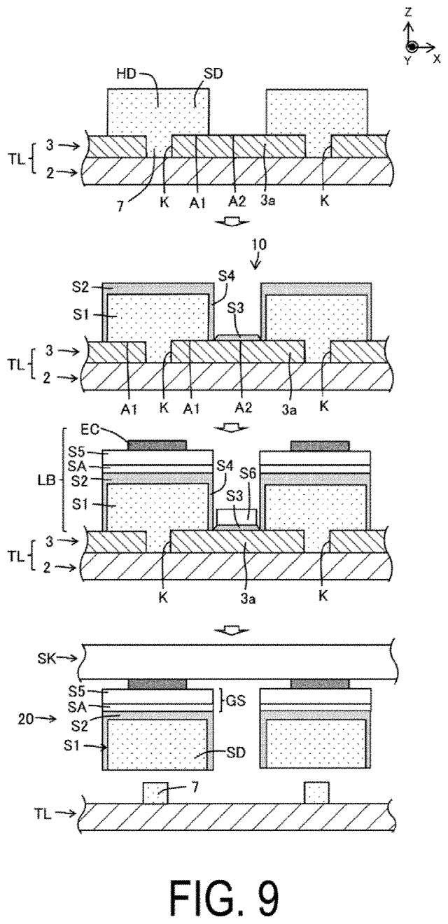

FIG. 7 is a plan view illustrating a method for producing a semiconductor device according to a second embodiment. FIG. 8 is a flowchart showing the method for producing the semiconductor device according to the second embodiment. FIG. 9 is a schematic cross-sectional view illustrating the method for producing the semiconductor device in FIG. 8. The production method illustrated in FIG. 7 to FIG. 9 includes: preparing a template substrate TL including an underlying substrate 2 and a mask 3 including an opening portion K and a mask portion 3a; forming a first semiconductor portion S1 from above the opening portion K over a first region A1 of the mask portion 3a though the ELO method; and forming a second semiconductor portion S2 located above the first semiconductor portion 51 and containing gallium (Ga) and a gallium congener (element in group 13), and a third semiconductor portion S3 located above a second region A2 of the mask portion 3a where the first semiconductor portion S1 is not formed and containing the gallium congener. The first region A1 and the second region A2 may be adjacent to each other, and the mask portion 3a may contain at least one of a silicon oxide and a silicon nitride. The third semiconductor portion S3 may also be referred to as a semiconductor portion located above the second region A2. The third semiconductor portion S3 may be a debris film. Here, the orientation from the underlying substrate 2 toward the first semiconductor portion S1 is referred to as “upward” (which may be opposite to the vertically upward direction).

In the ELO method, the first semiconductor portion S1 containing a nitride semiconductor (for example, GaN-based semiconductor) is grown in the lateral direction (X direction) from the opening portion K of the mask 3. Thus, a low-defect portion SD can be formed on the mask portion 3a, which is a selective growth mask. The low-defect portion SD has a smaller threading dislocation density than a dislocation inheriting portion HD on the opening portion K (a portion inheriting dislocations derived from the underlying substrate). The threading dislocation density is, for example, not more than 5×10⁶/cm² (not more than ⅕ of the threading dislocation density of the dislocation inheriting portion HD). Portions of semiconductor crystals formed above the low-defect portion SD inherit the low-defect property and have excellent crystallinity. In FIG. 7, FIG. 9, and the like, the <11-20> direction of the first semiconductor portion S1 is referred to as the X direction (a-axis direction), the <1-100> direction is referred to as the Y direction (m-axis direction), and the <0001> direction is referred to as the Z direction (c-axis direction). In the production method in FIG. 7 to FIG. 9, the semiconductor crystals (first semiconductor portions) growing laterally in opposite directions on the same mask portion 3a stop growing before they meet each other on the mask portion 3a, and the space (gap) between them corresponds to the second region A2.

By forming the first to third semiconductor portions S1 to S3 on the template substrate TL, a semiconductor substrate 10 that is a semiconductor device can be obtained. The semiconductor substrate 10 includes: the template substrate TL including the underlying substrate 2 and the mask 3 including the opening portion K and the mask portion 3a; the first semiconductor portion Si located from above the opening portion K over the first region A1 of the mask portion 3a; the second semiconductor portion S2 located above the first semiconductor portion Si and containing gallium and a gallium congener; and the third semiconductor portion S3 located above the second region A2 of the mask portion 3a where the first semiconductor portion S1 is not formed and containing the gallium congener. The first semiconductor portion S1 and the third semiconductor portion S3 are adjacent to each other in plan view (viewed in the Z direction). The second semiconductor portion S2 and the third semiconductor portion (semiconductor portion located above the second region A2) S3 may be formed in the same process, or may be formed in different processes.

The second semiconductor portion S2 and the third semiconductor portion S3 may each contain a nitride semiconductor, and the gallium congener contained in the second semiconductor portion S2 and the third semiconductor portion S3 may be aluminum. For example, the second semiconductor portion S2 and the third semiconductor portion S3 may contain aluminum gallium nitride (AlGaN). In this case, since the third semiconductor portion S3 (AlGaN layer) functions as a lid for the mask portion 3a (containing Si), unintended Si doping of semiconductor crystals formed above the second semiconductor portion S2 (transition of the raw material from the mask portion 3a) can be inhibited.

The aluminum gallium nitride contained in the third semiconductor portion S3 may have a different composition from that of the aluminum gallium nitride contained in the second semiconductor portion S2. The thickness of the third semiconductor portion S3 may be smaller than the thickness of the second semiconductor portion S2. This is because, while the second and third semiconductor portions S2 and S3 can be formed in the same step, states of crystal growth differ between the third semiconductor portion S3 (AlGaN layer) formed on the mask portion 3a (amorphous), which is a selective growth mask, and the second semiconductor portion S2 (AlGaN layer) formed on the first semiconductor portion S1, which is a GaN-based semiconductor crystal, for example.

The third semiconductor portion S3 may be in contact with the mask portion 3a. The second semiconductor portion S2 may be in contact with the upper surface of the first semiconductor portion S1. The second semiconductor portion S2 may be formed on the first semiconductor portion S1 with a nitride semiconductor portion serving as a buffer (for example, a GaN layer) interposed therebetween.

In the step of forming the second semiconductor portion S2 and the third semiconductor portion S3, a fourth semiconductor portion S4 (for example, AlGaN layer) along side surfaces of the first semiconductor portion S1 may be formed. When the mask portion 3a contains silicon, each of the first semiconductor portion S1 to the fourth semiconductor portion S4 may contain silicon. The bandgap of the GaN-based semiconductor (for example, AlGaN layer) contained in the second semiconductor portion S2 may be larger than the bandgap of the GaN-based semiconductor (for example, GaN layer) contained in the first semiconductor portion S1.

The gallium congener contained in the second semiconductor portion S2 and the third semiconductor portion S3 may be indium, and the second semiconductor portion S2 and the third semiconductor portion S3 may contain indium gallium nitride (InGaN). The second semiconductor portion S2 and the third semiconductor portion S3 may contain aluminum indium gallium nitride (AlInGaN). The gallium congener may be boron (B).

After the second and third semiconductor portions S2 and S3 are formed, a fifth semiconductor portion S5 may be formed above the second semiconductor portion S2. An active portion (active layer) SA may be formed above the second semiconductor portion S2, and then the fifth semiconductor portion S5 may be formed above the active portion SA. The active portion SA and the fifth semiconductor portion S5 may contain a GaN-based semiconductor. A sixth semiconductor portion S6 (for example, GaN-based semiconductor layer) may be formed above the third semiconductor portion S3.

The active portion SA may have a multiple quantum well (MQW). The active portion SA may include a light-emitting portion overlapping the low-defect portion SD in plan view. The fifth semiconductor portion S5 may be of the p-type, and may be a Mg-doped p-GaN layer, for example. The first semiconductor portion Si and the fifth semiconductor portion S5 may contain the same GaN-based semiconductor, and the first semiconductor portion S1 formed by the ELO method may be a Si-doped n-GaN layer, for example. The second semiconductor portion S2 to the fourth semiconductor portion S4 may be of the n-type, and may be a Si-doped n-AlGaN layer, for example.

The mask portion 3a, the first semiconductor portion S1, and the fifth semiconductor portion S5 may contain silicon, and the silicon concentration of the fifth semiconductor portion S5 may be not more than ⅕ of the silicon concentration of the first semiconductor portion S1. The third semiconductor portion S3 (for example, AlGaN layer) functions as a lid for the mask portion 3a (containing Si), and Si (n-type dopant) autodoping (transition of the raw material from the mask portion 3a) when forming the p-type fifth semiconductor portion S5 can be inhibited.

The fifth semiconductor portion S5 is not limited to being of the p-type, and may be of the undoped type (i-type). The third semiconductor portion S3 can inhibit Si autodoping when forming the fifth semiconductor portion S5.

As illustrated in FIG. 6B, the fifth semiconductor portion S5 may have a shape having an upper surface, side surfaces, and inclined surfaces that are adjacent to the upper surface and the side surfaces and inclined with respect to the upper surface and the side surfaces. When the fifth semiconductor portion 5S is being formed, the crystal growth of the sixth semiconductor portion S6 progresses even above the third semiconductor portion S3 (see FIG. 9), and thus the raw material is consumed and abnormal growth of the edges of the fifth semiconductor portion 5S (edge growth) is reduced.

After the fifth semiconductor portion S5 is formed, a step of forming an electrode EC or the like may be performed. After the electrode EC or the like is formed, a step of dividing a laminate LB including the first semiconductor portion 51, the second semiconductor portion S2, the fifth semiconductor portion S5, and the electrode EC into a plurality of pieces to make a plurality of semiconductor chips (semiconductor devices) 20 and a step of removing the mask portion 3a can be performed.

In the step of dividing the laminate LB (for example, dry etching step), the third semiconductor portion S3 on the mask portion 3a may be removed, and the mask portion 3a may be removed (for example, wet etched) after the third semiconductor portion S3 is removed. After the mask portion 3a is removed, a step of separating the first semiconductor portion 51 and the template substrate TL can be performed. For example, with the plurality of semiconductor chips 20 held by a support substrate SK, the connecting portion 7 between the first semiconductor portion 51 and the template substrate TL may be broken. Here, the connecting portion 7 may remain on the first semiconductor portion S1 side, on the template substrate TL side as illustrated in FIG. 9, or on both sides. As a result, the plurality of semiconductor chips 20 can be obtained.

The semiconductor chips (semiconductor devices) 20 are each, for example, a light-emitting diode (LED) chip, a laser chip, a transistor chip, or the like (described below).

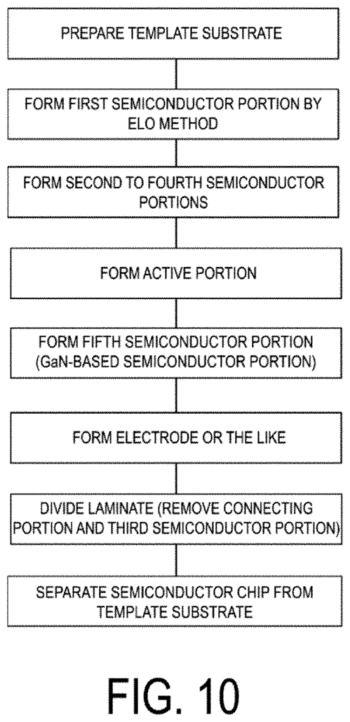

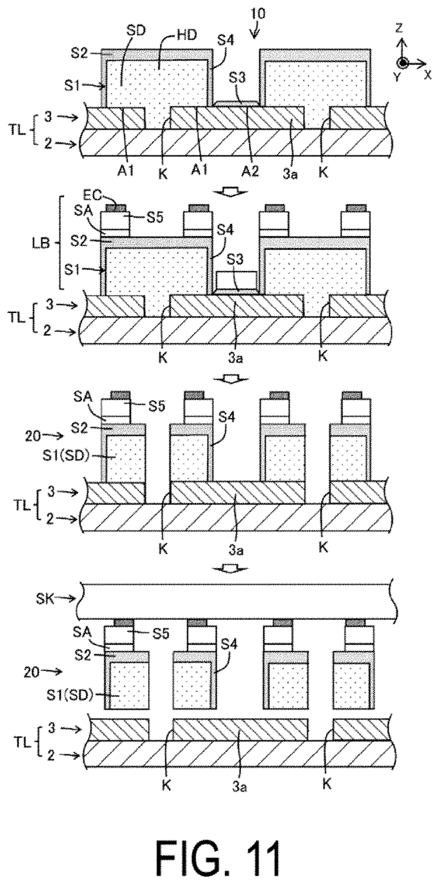

FIG. 10 is a flowchart illustrating another method for producing the semiconductor device according to the second embodiment. FIG. 11 is a schematic cross-sectional view illustrating the method for producing the semiconductor device in FIG. 10. In FIG. 10 and FIG. 11, in the step of dividing the laminate LB after the fifth semiconductor portion S5 and the electrode EC or the like are formed, the connecting portion 7 between the template substrate TL and the first semiconductor portion S1 is removed (together with the dislocation inheriting portion HD). In the step of removing the connecting portion 7, the third semiconductor portion S3 may be removed. In this way, the plurality of semiconductor chips (semiconductor devices) 20 can be obtained with the mask portion 3a remaining in the template substrate TL.

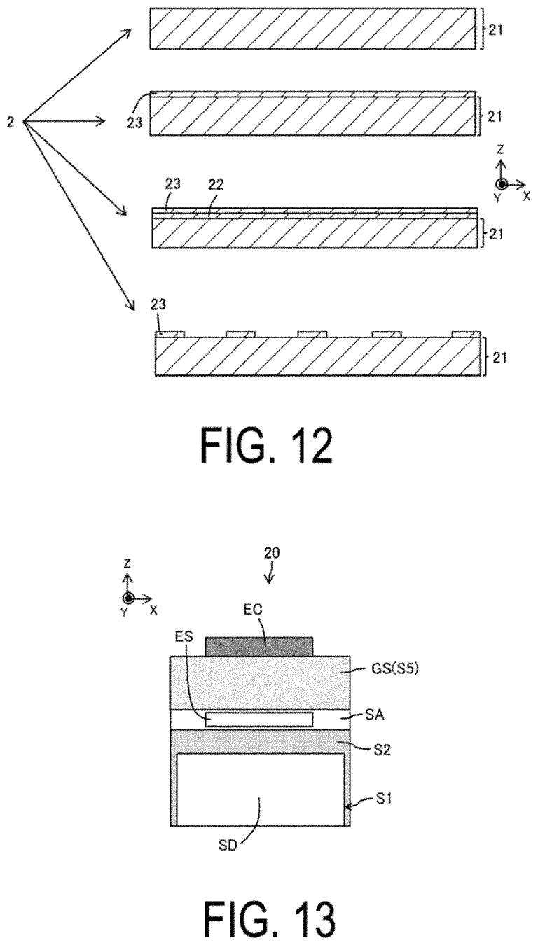

FIG. 12 is a cross-sectional view illustrating a configuration of an underlying substrate according to the second embodiment. The underlying substrate 2 may include a main substrate 21 (for example, GaN substrate, hexagonal crystal SiC substrate, AlN substrate, or the like) that is a bulk crystal substrate. In this case, the upper surface of the main substrate 21 exposed from the opening portion K of the mask 3 is the growth starting point of the first semiconductor portion S1.

The underlying substrate 2 may be configured to include the main substrate 21 (bulk crystal heterogeneous substrate) having a different lattice constant from that of the GaN-based semiconductor, and a seed portion 23. The main substrate 21, which is a heterogeneous substrate, is a Si substrate, a SiC substrate, an AlN substrate, a sapphire substrate, or the like, for example. In this case, a Si substrate may be used for the main substrate 21 and AlN or SiC for the seed portion 23, or a SiC substrate may be used for the main substrate 21 and a GaN-based semiconductor (for example, GaN) for the seed portion 23. When the underlying substrate 2 includes the seed portion 23, the upper surface of the seed portion 23 exposed from the opening portion K of the mask 3 is the growth starting point of the first semiconductor portion S1 (see FIG. 7).

Alternatively, the underlying substrate 2 may be configured to include the main substrate 21, which is a bulk crystal heterogeneous substrate, a buffer portion 22, and the seed portion 23. If the Si substrate and the GaN-based semiconductor are in direct contact with each other, they may melt together. This can be avoided by providing the buffer portion 22. For example, a Si substrate may be used for the main substrate 21, at least one of AlN or SiC for the buffer portion 22, and a GaN-based semiconductor for the seed portion 23.

The seed portion 23 may be formed entirely, or may be formed locally as illustrated in the bottom row in FIG. 12. For example, the opening portion K of the mask 3 may have a slit shape (see FIG. 7), and the seed portion 23 may have a longitudinal shape overlapping with the opening portion K.

FIG. 13 is a cross-sectional view illustrating a configuration of the semiconductor device according to the second embodiment. The semiconductor device (semiconductor chip) 20 in FIG. 13 includes a first semiconductor portion S1 containing a GaN-based semiconductor (for example, GaN) and including a low-dislocation portion SD having a threading dislocation density of not more than 5×10⁶/cm², a second semiconductor portion S2 located above the first semiconductor portion 51 and containing gallium and a gallium congener, an active portion SA located above the second semiconductor portion S2, a p-type GaN-based semiconductor portion GS (fifth semiconductor portion S5) located above the active portion SA, and an electrode EC (for example, anode) in contact with the GaN-based semiconductor portion GS. Although not illustrated, for example, a cathode in contact with the second semiconductor portion S2 can be provided.

The semiconductor device 20 in FIG. 13 is a light-emitting diode (LED) chip, and the active portion SA includes a light-emitting portion ES overlapping with the low-dislocation portion SD above the low-dislocation portion SD. That is, the light-emitting portion ES is included between the second semiconductor portion S2 and the GaN-based semiconductor portion GS. The gallium congener may be aluminum, and the second semiconductor portion S2 may be a nitride semiconductor layer containing Al (for example, AlGaN layer). The first semiconductor portion S1 can be a nitride semiconductor layer formed by the ELO method using a selective growth mask containing silicon, and the first and second semiconductor portions S1 and S2 may each contain silicon. The second semiconductor portion S2 may extend to the side surfaces of the first semiconductor portion S1.

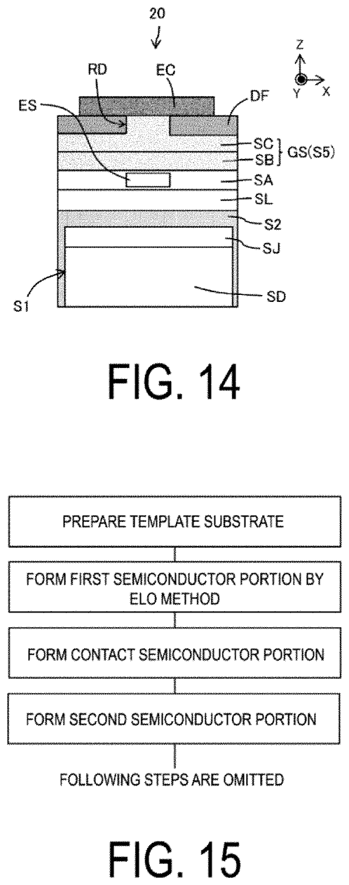

FIG. 14 is a cross-sectional view illustrating another configuration of the semiconductor device according to the second embodiment. FIG. 15 is a flowchart showing a method for producing the semiconductor device in FIG. 14. The semiconductor device (semiconductor chip) 20 in FIG. 14 is a laser chip and includes a first semiconductor portion S1 containing a GaN-based semiconductor (for example, GaN) and including a low-dislocation portion SD having a threading dislocation density SD of not more than 5×10⁶/cm².

Above the first semiconductor portion S1, an n-type contact portion SJ, a second semiconductor portion S2 that is an n-type cladding portion, an n-type light guide portion SL, an active portion (active layer) SA including a light-emitting portion ES, a GaN-based semiconductor portion GS (fifth semiconductor portion) including a p-type light guide portion SB and a p-type cladding portion SC, and an electrode EC are disposed in this order. The p-type cladding portion SC may include a ridge portion RD (current constriction portion), both sides of the ridge portion RD may be provided with insulating films DF, and the electrode EC (for example, anode) may be in contact with the p-type cladding portion SC and the insulating films DF. The second semiconductor portion S2 may extend to the side surfaces of the contact semiconductor portion SJ. The first semiconductor portion S1 can be a nitride semiconductor layer formed by the ELO method using a selective growth mask containing silicon, and the first and second semiconductor portions S1 and S2 may each contain silicon. The second semiconductor portion S2 may be a nitride semiconductor layer (for example, AlGaN layer) containing Al. Although not illustrated, for example, a cathode in contact with the contact semiconductor portion SJ can be provided.

In FIG. 15, a step of forming the first semiconductor portion S1 (for example, GaN layer) by the ELO method and a step of forming an n-type contact semiconductor portion SJ (for example, n-GaN layer) are performed, and then a step of forming the second semiconductor portion S2 (for example, n-AlGaN layer) is performed.

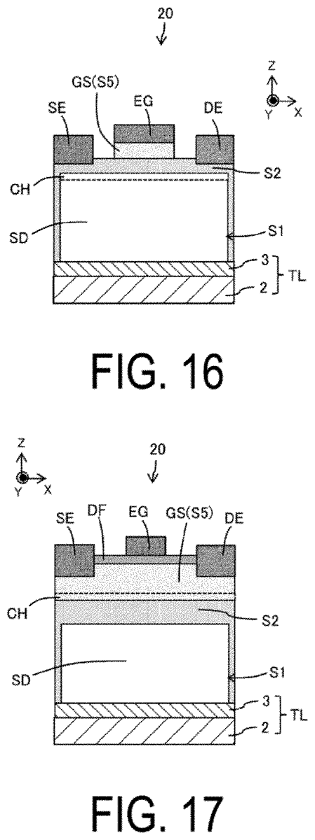

FIG. 16 is a cross-sectional view illustrating another configuration of the semiconductor device according to the second embodiment. The semiconductor device 20 in FIG. 16 is a transistor chip (also referred to as an HEMT), includes a first semiconductor portion Si containing a GaN-based semiconductor (for example, GaN) and including a low-dislocation portion SD having a threading dislocation density of not more than 5×10⁶/cm², a second semiconductor portion S2 located above the first semiconductor portion S1 and containing gallium and a gallium congener, a GaN-based semiconductor portion GS (fifth semiconductor portion) located on the second semiconductor portion S2, a source electrode SE and a drain electrode DE in contact with the second semiconductor portion S2, and a gate electrode EG located on the GaN-based semiconductor portion GS. The first semiconductor portion Si can be formed by the ELO method.

The first semiconductor portion Si (for example, GaN layer) includes a channel portion CH (two-dimensional electron gas) near the interface with the second semiconductor portion S2 (for example, AlGaN layer having a larger bandgap than that of the GaN layer). The channel portion CH is an n-channel, and is turned ON (becomes conductive) by providing the gate electrode EG with a potential that is higher than a threshold potential. The first semiconductor portion Si may be of the n-type, or may be of the i-type (undoped type). The second semiconductor portion S2 may be of the n-type, or may be of the i-type.

The transistor chip in FIG. 16 has high electron mobility and high voltage resistance, and can be used for high-frequency devices, power devices (power control devices), and the like.

FIG. 17 is a cross-sectional view illustrating another configuration of the semiconductor device according to the second embodiment. The semiconductor device (semiconductor chip) 20 in FIG. 17 is a transistor chip (also referred to as an inverted HEMT), includes a first semiconductor portion Si (for example, GaN layer) containing a GaN-based semiconductor (for example, GaN) and including a low-dislocation portion SD having a threading dislocation density of not more than 5×10⁶/cm², a second semiconductor portion S2 located above the first semiconductor portion Si and containing gallium and a gallium congener, a GaN-based semiconductor portion GS (fifth semiconductor portion) located on the second semiconductor portion S2, a source electrode SE and a drain electrode DE in contact with the GaN-based semiconductor portion GS, and a gate electrode EG disposed above the GaN-based semiconductor portion GS with an insulating film DF interposed therebetween. The first semiconductor portion Si can be formed by the ELO method.

The GaN-based semiconductor portion GS (for example, GaN layer) includes a channel portion CH (two-dimensional electron gas) near the interface with the second semiconductor portion S2 (for example, AlGaN layer having a larger bandgap than that of the GaN layer). The channel portion CH is an n-channel, and is turned OFF by providing the gate electrode EG with a potential that is lower than the threshold potential.

The underlying substrate 2 may be a SiC substrate, and the growth surfaces of the first semiconductor portion S1 and the second semiconductor portion S2 may each be a (000-1) plane (−c plane, nitrogen polar face). The first semiconductor portion Si may be of the n-type, or may be of the i-type (undoped type). The second semiconductor portion S2 may be of the n-type, or may be of the i-type.

The transistor chip in FIG. 17 has high electron mobility and high voltage resistance, and can be used for high-frequency devices, power devices (power control devices), and the like.

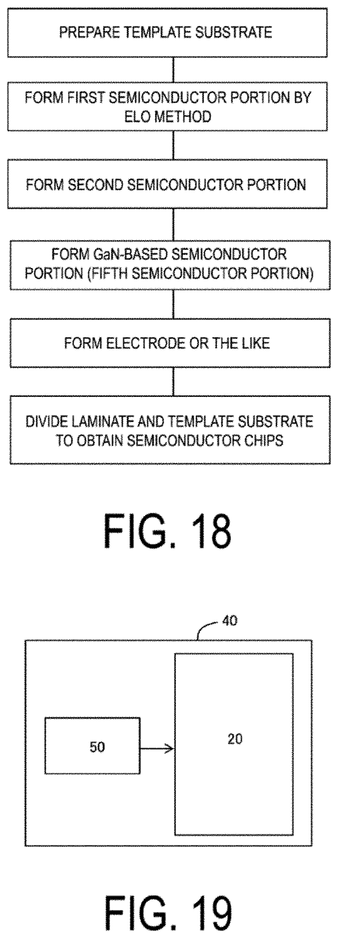

FIG. 18 is a flowchart illustrating a method for producing the semiconductor device in FIG. 16 and FIG. 17. In FIG. 18, a step of forming the first semiconductor portion Si (for example, GaN layer) by the ELO method, a step of forming the second semiconductor portion S2 (for example, AlGaN layer), a step of forming the GaN-based semiconductor portion GS, and a step of forming the electrodes (SE, EG, DE) or the like are performed, and then a step of dividing a laminate including the first semiconductor portion S1, the second semiconductor portion S2, and the GaN-based semiconductor portion GS as well as a template substrate TL to obtain the semiconductor device 20, which is a semiconductor chip, is performed.

FIG. 19 is a schematic diagram illustrating a configuration of an electronic device according to the second embodiment. An electronic device 40 includes a semiconductor device 20 and a controller 50 including a processor that controls the semiconductor device 20. Examples of the electronic device 40 include a communication device, a power control device, an optical device, a display device, an illumination device, a sensor device, a measurement device, an information processing device, a medical device, and an electric vehicle (EV).

The present disclosure has been described in detail above, but the present disclosure is not limited to the embodiments described above, and various modifications, improvements, and the like can be made within a scope not departing from the gist of the present disclosure. Needless to say, all or a part of each of the above-described embodiments can be appropriately combined in a non-contradicting range.

### REFERENCE SIGNS

1 Growth surface
1a Partial region of growth surface 1
1b Crystal growth region
2 Substrate (underlying substrate)
3 Deposition inhibiting mask (mask)
4 First semiconductor layer
5 Second semiconductor layer
5′ Non-single-crystal film
6 Semiconductor element portion
7 Connecting portion
10 Semiconductor epitaxial substrate (semiconductor substrate, semiconductor device)
20 Semiconductor chip (semiconductor device)

1. A method for producing a semiconductor device, the method comprising:
preparing a semiconductor substrate comprising an underlying substrate, a mask comprising an opening portion and a mask portion that includes a first region and a second region, and a first semiconductor portion formed from above the opening portion over the first region; and
forming a semiconductor portion containing a gallium congener and located above the second region where the first semiconductor portion is not formed.

2. The method for producing a semiconductor device according to claim 1, wherein
the gallium congener is aluminum.

3. The method for producing a semiconductor device according to claim 1, further comprising:
forming a second semiconductor portion located above the first semiconductor portion and containing the gallium congener and gallium.

4. The method for producing a semiconductor device according to claim 3, wherein
the semiconductor portion located above the second region and the second semiconductor portion each contain a nitride semiconductor.

5. The method for producing a semiconductor device according to claim 4, wherein
the nitride semiconductor is aluminum gallium nitride.

6. The method for producing a semiconductor device according to claim 5, wherein
the aluminum gallium nitride contained in the semiconductor portion located above the second region has a different composition from that of the aluminum gallium nitride contained in the second semiconductor portion.

7. The method for producing a semiconductor device according to claim 3, wherein
in the forming of the semiconductor portion located above the second region and the second semiconductor portion, a fourth semiconductor portion along side surfaces of the first semiconductor portion is formed.

8. The method for producing a semiconductor device according to claim 3, wherein
the second semiconductor portion is in contact with an upper surface of the first semiconductor portion.

9. The method for producing a semiconductor device according to claim 1, wherein
the mask portion comprises at least one of a silicon oxide and a silicon nitride.

10. The method for producing a semiconductor device according to claim 9, wherein
the semiconductor portion located above the second region is in contact with the mask portion.

11. The method for producing a semiconductor device according to claim 9, wherein
the first semiconductor portion contains silicon and a GaN-based semiconductor.

12.-15. (canceled)

16. The method for producing a semiconductor device according to claim 3, wherein
a thickness of the semiconductor portion located above the second region is smaller than a thickness of the second semiconductor portion.

17. (canceled)

18. The method for producing a semiconductor device according to claim 3, wherein
after the semiconductor portion located above the second region is formed, a fifth semiconductor portion located above the second semiconductor portion is formed, and
after the fifth semiconductor portion is formed, the semiconductor portion located above the second region is removed.

19.-22. (canceled)

23. The method for producing a semiconductor device according to claim 11, wherein
the underlying substrate comprises a main substrate, and
the main substrate is a heterogeneous substrate having a different lattice constant from that of the GaN-based semiconductor.

24. The method for producing a semiconductor device according to claim 23, wherein
the underlying substrate comprises a seed portion located above the main substrate, and
the seed portion is exposed from the opening portion.

25. The method for producing a semiconductor device according to claim 24, wherein
the opening portion has a slit shape, and
the seed portion has a longitudinal shape overlapping with the opening portion.

26.-27. (canceled)

28. A semiconductor substrate comprising:
a template substrate comprising an underlying substrate and a mask comprising an opening portion and a mask portion that includes a first region and a second region;
a first semiconductor portion located from above the opening portion over the first region; and
a semiconductor portion containing a gallium congener and located on the second region where the first semiconductor portion is not formed.

29. A semiconductor device comprising:
a first semiconductor portion containing a GaN-based semiconductor and including a low-dislocation portion having a threading dislocation density of not more than 5×106/cm2;
a second semiconductor portion located above the first semiconductor portion and containing gallium and a gallium congener; and
a GaN-based semiconductor portion located above the second semiconductor portion and being of a p-type or an undoped type.

30. The semiconductor device according to claim 29, wherein
the gallium congener is aluminum, and
the first and second semiconductor portions each contain silicon.

31.-45. (canceled)

46. The semiconductor substrate according to claim 28, wherein
the gallium congener is aluminum, and
the first semiconductor portion and the semiconductor portion located on the second region each contain silicon.
